(19) United States
(12) Patent Application Publication
(10) Pub. No.: US 2015/0079722 A1
(43) Pub. Date: Mar. 19, 2015

(54) AVALANCHE PHOTODIODE WITH A GUARD RING STRUCTURE AND METHOD THEREOF

(71) Applicant: ELECTRONICS AND TELECOMMUNICATIONS RESEARCH INSTITUTE, Daejeon (KR)

(72) Inventors: Bongki MHEEN, Daejeon (KR); Myoungsook OH, Daejeon (KR); Kisoo KIM, Daejeon (KR); Jae-Sik SIM, Daejeon (KR); Yong-Hwan KWON, Daejeon (KR); Eun Soo NAM, Daejeon (KR)

(73) Assignee: ELECTRONICS AND TELECOMMUNICATIONS RESEARCH INSTITUTE, Daejeon (KR)

(21) Appl. No.: 14/553,968

(22) Filed: Nov. 25, 2014

Related U.S. Application Data
(62) Division of application No. 13/689,163, filed on Nov. 29, 2012.

(30) Foreign Application Priority Data
Aug. 7, 2012 (KR) 10-2012-0086230

(51) Int. Cl. H01L 31/18; H01L 31/0352; H01L 31/107

(52) U.S. Cl. CPC H01L 31/18; H01L 31/107; H01L 31/035272
USPC 438/91

(57) ABSTRACT

Disclosed are an avalanche photodiode with a guard ring structure that relieves edge breakdown by an external voltage which is applied through a metal pad which is attached to the guard ring and a manufacturing method thereof. An avalanche photodiode with a guard ring structure includes a plurality of semiconductor layers laminated on a substrate; an active region partially formed above the semiconductor layers; a guard ring which is formed above the semiconductor layers and disposed so as to be spaced apart from the active region and have a ring shape that encloses the active region; and a connecting unit formed on the semiconductor layers to be electrically connected to the guard ring so as to apply an external voltage to the guard ring region. Therefore, the external voltage is applied to the guard ring of the avalanche diode through the connecting unit to relieve the edge breakdown.

### CROSS-REFERENCE TO RELATED APPLICATIONS

The present application is a Divisional Application of co-pending U.S. Application No. 13/689,163, filed on Nov. 29, 2012, which claims priority from Korean Patent Application No. 10-2012-0086230, filed on Aug. 7, 2012, with the Korean Intellectual Property Office, the disclosure of which is incorporated herein in its entirety by reference.

### TECHNICAL FIELD

The present disclosure relates to an avalanche photodiode with a guard ring structure and a manufacturing method thereof, and more specifically, to an avalanche photodiode with a guard ring structure that relieves edge breakdown by an external voltage which is applied through an additional metal pad which is attached to the guard ring without changing the structure of the guard ring and a manufacturing method thereof.

### BACKGROUND

As amount of information communication is increased, large quantity and ultrahigh speed information communication system is required. In a backbone network, it is expected that a total transmission amount may be several hundreds or several terabytes with a several tens of gigabytes of band as a basic transmission amount.

In the meantime, a receiver of medical or three-dimensional image radar also requires a high sensitive photo detector. In this case, if a photo detector having a higher receiving sensitivity is used, good transmission quality and excellent image data may be obtained without using a light amplifier. Here, an avalanche photodiode (APD) is used as a light receiving element of a photo detector having a high receiving sensitivity.

The avalanche photodiode(APD) uses avalanche multiplication which is generated by applying a high electric field to a hole or an electron generated when a high electric field is generated to generate a gain of a signal.

As compared with the avalanche photodiode, a PIN or PN diode amplifies an electron-hole pair (EHP) generated by light using a pre-amplifier or a trans-impedance amplifier (TIA) which is connected next to the photo diode. However, in this method, noise is increased due to a subsequent amplifier, which reduces sensitivity at a receiver side such as an overall increase of an input noise level. However, when using a gain of the avalanche photodiode, the reduction of sensitivity at the receiver may be prevented. Noise may be additionally generated even when the signal is amplified in the avalanche photodiode. However, the gain of the signal is larger than the generated noise so that it is advantageous in a view of a signal-noise ratio (SNR). Therefore, it is possible to establish excellent receiver sensitivity as compared with the PIN or PN diode which does not have a gain in an element level.

In order to prevent the receiver sensitivity from being reduced using a gain of the avalanche photodiode, avalanche needs to be evenly generated in an amplifying layer which corresponds to a region that generates the avalanche of the avalanche photodiode.

If an intensity of an electric field becomes stronger in a specific region so that the avalanche is concentrated in this region, it is difficult to obtain an even amplification characteristic. This situation is generally referred to as “edge breakdown”.

A more serious problem is that the noise characteristic becomes much worse in the edge breakdown as compared with a secured gain characteristic, which lowers the SNR. As a result, it is important to obtain a constant avalanche gain while suppressing the noise as much as possible. Therefore, elements need to be designed so as to appropriately prevent the edge breakdown.

For this reason, various types of guard ring designs need to be reflected into a design of an avalanche photodiode. Therefore, the number of guard rings which will be provided, a shape, a position of guard ring, a width, and an interval may be optimized, which requires a lot of efforts. The condition may be varied depending on a size of the signal which is applied to the avalanche photodiode. In other words, the optimized design of the guard ring may be varied depending on a situation where a large signal is applied and a situation where a small signal is applied.

### SUMMARY

The present disclosure has been made in an effort to provide an avalanche diode with a guard ring structure that is capable of controlling edge breakdown in the process of obtaining an avalanche gain of an avalanche diode by applying an external voltage to a guard ring of the avalanche diode.

An exemplary embodiment of the present disclosure provides an avalanche photodiode with a guard ring structure, including: a plurality of semiconductor layers laminated on a substrate; an active region formed on the semiconductor layers; a guard ring disposed so as to be spaced apart from the active region and formed to have a ring shape that encloses the active region; an electrode formed on the active region; and a contact portion formed of an electric conductive material on the guard ring.

The contact portion may apply an external voltage to the guard ring and the external voltage may be determined by referring to a voltage detected from the electrode.

The contact portion may be connected to a separate metal pad in order to easily apply the external voltage.

Another exemplary embodiment of the present disclosure provides a method of manufacturing an avalanche photodiode with a guard ring structure, including: sequentially forming a plurality of semiconductor layers on a substrate; forming an active region on the semiconductor layers using a patterned diffusion mask through a diffusing process; forming a guard ring so as to be spaced apart from the active region and have a ring shape that encloses the active region; and forming a contact portion formed of a electric conductive material on the guard ring.

The conductive material may have a capacitance value determined by considering a voltage which is guided to the guard ring by capacitor coupling with the guard ring.

The plurality of semiconductor layers may be formed by sequentially laminating an optical absorber layer, a grading layer, a charge layer, and an amplifying layer.

The forming of the contact portion may include: forming an insulating layer on the semiconductor layers on which the guard ring is formed; patterning the insulating layer to etch a patterned portion; and forming the contact portion by depositing a metal on the patterned portion so as to be connected to the guard ring.

According to the present disclosure, the edge breakdown may be relieved by applying an external voltage to a guard ring of an avalanche diode.

According to the present disclosure, a method of preventing edge breakdown may be applied to the design of the guard ring of the known avalanche diode and also controlled by a voltage which is applied to the guard ring, which allows a degree of freedom in the design of a guard ring. Therefore, it is possible to achieve more efficient design and ensure excellent performance.

According to the present disclosure, by adjusting an external voltage which is applied to the guard ring of the avalanche diode, an avalanche gain may be controlled.

According to the present disclosure, the edge breakdown condition is varied depending on the size of an optical signal which is input to the avalanche diode. Accordingly, by considering the above condition, a voltage which is applied to the guard ring is varied to obtain a condition to prevent edge breakdown which is optimized to the size of the input optical signal, which may improve the performance.

According to the present disclosure, when the voltage which is applied to the guard ring is varied, in addition to an effect to restrict the edge breakdown, an amplification factor (M value, multiplication factor) that is generated in an amplifying layer (multiplication layer) is also affected, which may improve the characteristic of the avalanche photodiode.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view of an APD structure according to an exemplary embodiment of the present disclosure.

FIGS. 2A to 2C are views illustrating a method of manufacturing an APD according to an exemplary embodiment of the present disclosure.

FIG. 3 is a plan view of the APD structure which is implemented by an array according to an exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

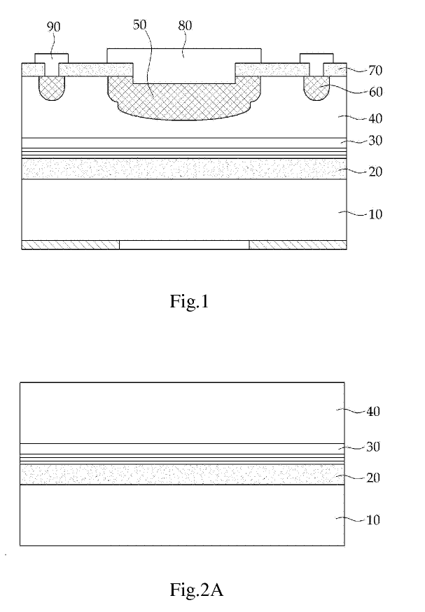

FIG. 1 is a view illustrating a structure of an avalanche photodiode (APD) having a guard ring structure according to an exemplary embodiment of the present disclosure.

As illustrated in FIG. 1, the avalanche photodiode having a guard ring structure includes a substrate 10, a plurality of semiconductor layers 20, 30, and 40, an active region 50, a guard ring 60, an insulating layer 70, an electrode 80, and a contact portion 90.

More specifically, as seen from the cross-section view of the avalanche photodiode, the avalanche photodiode with a guard ring is configured such that an optical absorber layer 20, a charge layer 30, and an amplifying layer 40 are sequentially laminated on the substrate 10 and the active region 50 and the guard ring 60 are formed in the amplifying layer 40.

The guard ring 60 is formed so as to be electrically separated from the active region 50 and have a ring shape that encloses the active region 50. The guard ring 60 is disposed to be spaced apart from the amplification region (active region 50) with a predetermined interval in order to reduce a peak of the electric field which is concentrated at an outer side of the amplification region (active region 50).

The insulating layer 70 is formed on the amplifying layer 40 in which the guard ring 60 is formed and the electrode 80 is formed on the insulating layer 70 so as to be connected to the active region 50. The contact portion 90 is formed on the insulating layer 70 so as to be connected to the guard ring 60.

The contact portion 90 is in contact with the guard ring 60 and formed of electric conductive material to apply an external voltage to the guard ring 60.

If the contact portion 90 applies the external voltage to the guard ring 60, the shape or size thereof may be varied.

Here, the external voltage is manually controlled by referring to a voltage which is detected from the electrode 80. Therefore, the external voltage is applied so as to be controlled to restrict the edge breakdown of the guard ring 60.

An additional metal pad (not illustrated) is connected to the contact portion 90 so that the external voltage may be applied through the metal pad.

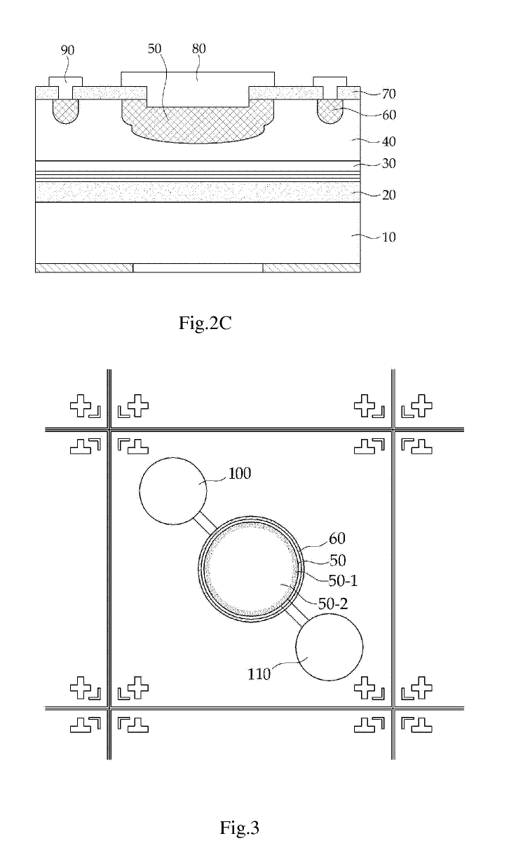

FIG. 3 is a plan view of the avalanche photodiode to which a metal pad is connected according to an exemplary embodiment of the present disclosure.

Next, referring to FIGS. 1 and 3, if a separate metal pad 100 is connected to the contact portion 90, the metal pad 100 guides the voltage to the guard ring 60 by capacitor coupling with the guard ring 60. In other words, the metal pad 100 is disposed so as to be adjacent to the contact portion 90 so that a capacitance value of the metal pad 100 affects the voltage which is guided to the guard ring 60. Therefore, the capacitance value of the metal pad 100 is adjusted so as to guide a required voltage to the guard ring 60.

With this configuration, without changing a structure of the guard ring, the voltage is applied from the outside to control an amplification gain of the guard ring 60.

Definitely, a voltage of the active region 50 is detected from a metal pad 110 which is connected to the electrode (80 in FIG. 1) to apply the external voltage to the metal pad 100 referring to the detected voltage to control a voltage of the guard ring 60.

In the meantime, in this embodiment of the present disclosure, the metal pad is formed to be circular due to interconnection for wire bonding. However, if a voltage is applied between the meal pad 100 and the guard ring 60 by the capacitor coupling, the metal pad may have a different shape.

A method of manufacturing an avalanche photodiode having a guard ring structure according to an exemplary embodiment of the present disclosure will be described below.

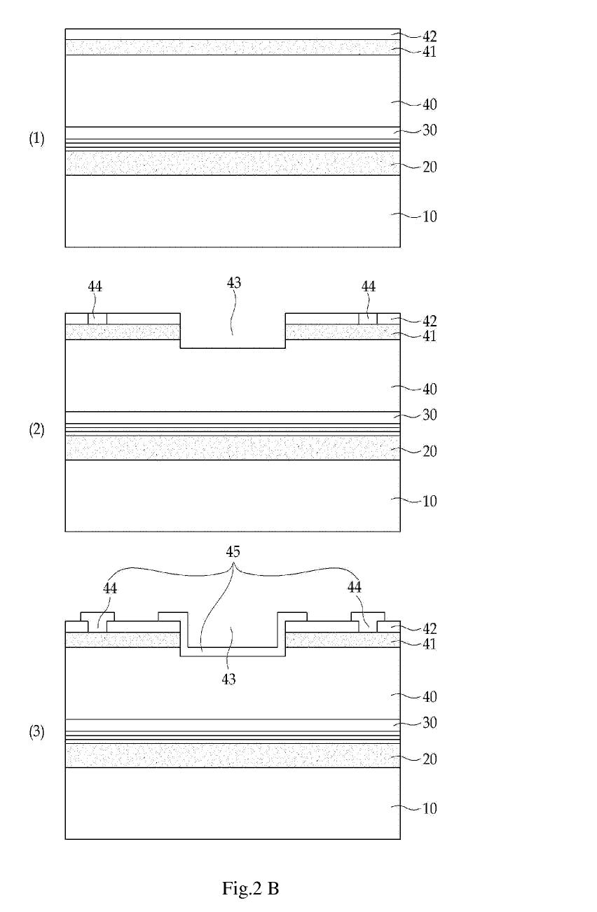

First, as illustrated in FIG. 2A, on the substrate 10, the optical absorber layer 20, the charge layer 30, and the amplifying layer 40 are sequentially laminated.

In this case, if the substrate 10, component materials of the layers and a method of forming the layers are known in the art, these are not specifically limited. Specifically, a crystal thin film growing equipment such as a metal organic chemical vapor deposition (MOCVD) device or molecular beam epitaxy (MBE) may be used.

Next, after forming a patterned diffusing mask above the semiconductor layer, the active region 50 is formed through a diffusing process. The guard ring 60 is formed to be spaced apart from the active region 50 and have a ring shape that encloses the active region 50.

Various methods of forming the active region 50 and the guard ring 60 are known to a skilled person in the art and a method that uses a diffusing mask will be described as an example.

As illustrated in (1) of FIG. 2B, a diffusion layer 41 is formed on the amplifying layer 40 which is a region where the active region 50 is to be formed and a protection layer 42 is formed on the diffusion layer 41.

Generally, a process that diffuses diffusant onto the amplifying layer 50 is carried out at a high temperature of 500° C. or higher. In this case, if the diffusion layer 41 is exposed, the diffusion layer 41 may be broken due to the high temperature. Accordingly, the protection layer 42 is formed so as to protect the diffusion layer 41 from the high temperature. Even though a material for the protection layer 42 is not specifically limited, silicon dioxide (for example, SiO₂) or silicon nitride (for example, Si₃N₄) may be used. A method of forming the protection layer 42 is not specifically limited, but a plasma deposition method may be used.

As illustrated in (2) of FIG. 2B, the amplifying layer is etched from the protection layer 40 to a predetermined depth such that a first etched portion 43 is formed at a position where the active region 50 is to be formed and a second etched portion 44 is formed at a position where the guard ring 60 is to be formed. A method of forming an etching portion 108 is not specifically limited, but a dry etching method is used to perform recess etching. The extent of the etching is determined by considering a time and a depth for and at which the diffusant is diffused.

Continuously, as illustrated in (3) of FIG. 2B, a diffusion process is carried out on the first etched portion 43 and the second etched portion 44 to form the active region (center part and peripheral part) 50 and the guard ring 60 on the amplifying layer 40. At the time of diffusing using a diffusion mask 45 as a mask, a thickness of the etched amplifying layer 40 is varied so that the center part of the active region (50-2 of FIG. 3) is larger than the peripheral part (50-1 of FIG. 3).

Continuously, the diffusion mask 45, the diffusion layer 41, and the protection layer 42 are removed. Even though the method of removing the diffusion mask is not specifically limited, a wet-etching method using a solution in which a phosphate based compound is diluted may be used.

Thereafter, as illustrated in FIG. 2C, the insulating layer 70 is formed on the semiconductor layer on which the guard ring 60 is formed and then the electrode 80 which is connected to the active region 50 and the contact portion 90 which is connected to the guard ring 60 are formed on the amplifying layer 40.

A material for the insulating layer 70 is not specifically limited. As an unrestricted example, silicon nitride (for example, Si₃N₄) or silicon dioxide (for example, SiO₂) may be used. If a method of forming the insulating layer 70 is known in the art, the method is not specifically limited. However, plasma enhanced chemical vapor deposition (PECVD) or sputter may be used.

Thereafter, the formed insulating layer 70 is patterned and an electrode material is deposited thereon to form the electrode 80 and the contact portion 90.

Here, if a method of patterning the insulating layer 70 is known in the art, the method is not specifically limited. However, a photolithography process is used to partially pattern the insulating layer 70 and then the insulating layer 70 is etched and formed with a reaction gas in which O₂ gas is added to C₂F₆.

A method of forming the electrode and the contact portion after patterning the insulating layer 70 is not specifically limited if the method is known in the art.

When the avalanche photodiode according to the exemplary embodiment of the present disclosure is applied to a laser RADAR (or LADAR), a dynamic range of a signal which is reflected by adjusting an external voltage may be much widened. If a structure thereof is slightly changed, the avalanche photodiode may be driven even with a structure capable of reducing a detection size of the avalanche photodiode. In this case, an observation range of the laser RADAR may be increased or reduced so that the avalanche photodiode may function as an aperture of a general camera.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method of manufacturing an avalanche photodiode with a guard ring structure, comprising:
sequentially forming a plurality of semiconductor layers on a substrate;
forming an active region on the semiconductor layers using a patterned diffusion mask through a diffusing process;
forming a guard ring so as to be spaced apart from the active region and have a ring shape that encloses the active region; and
forming a contact portion formed of a conductive material on the guard ring.

2. The method of claim 1, wherein the conductive material has a capacitance value determined by considering a voltage which is guided to the guard ring by capacitor coupling with the guard ring.

3. The method of claim 1, wherein the plurality of semiconductor layers are formed by sequentially laminating an optical absorber layer, a grading layer, a charge layer, and an amplifying layer.

4. The method of claim 1, wherein the forming of the contact portion includes:
forming an insulating layer on the semiconductor layers on which the guard ring is formed;
patterning the insulating layer to etch a patterned portion; and
forming the contact portion by depositing a metal on the patterned portion so as to be connected to the guard ring.
